(19) United States
(12) Patent Application Publication
(10) Pub. No.: US 2025/0112112 A1
(43) Pub. Date: Apr. 3, 2025

(54) TECHNOLOGIES FOR DIAMOND COMPOSITE MATERIALS MANUFACTURED VIA FIELD-ASSISTED SINTERING TECHNOLOGY

(71) Applicant: Intel Corporation, Santa Clara, CA (US)

(72) Inventor: Carin Ruiz, Portland, OR (US)

(73) Assignee: Intel Corporation, Santa Clara, CA (US)

(21) Appl. No.: 18/479,015

(22) Filed: Sep. 30, 2023

(51) Int. Cl. H01L 23/373; C22C 26/00; H01L 23/367

(52) U.S. Cl. CPC H01L 23/3732; C22C 26/00; H01L 23/3672

(57) ABSTRACT

Technologies for diamond composite materials are disclosed. In one embodiment, field-assisted sintering technology (FAST) is used to create a diamond composite material that includes diamond particles, copper, and chromium. The chromium can help bond the copper and the diamond particles. The diamond composite material has a high thermal conductivity, such as 500-1,000 W/(m·K). In one embodiment, the diamond composite material may be used in an integrated heat spreader in an integrated circuit component. In other embodiments, the diamond composite material may be used in a heat sink, a cold plate, an internal frame, a chassis, etc.

### BACKGROUND

As the number of transistors on a die and in a package continues to increase, the amount of power dissipated in a die or a package tends to increase as well. Thermal management is becoming one factor that can limit the performance of dies, such as processor dies. Integrated heat spreaders help distribute heat away from hot spots on dies, and cold plates and heat sinks are used to transfer heat away from the integrated heat spreaders. Integrated heat spreaders are commonly made from materials with a high thermal conductivity, such as copper. Integrated heat spreaders made with materials with a higher thermal conductivity would allow for better heat removal from the dies in a package.

### BRIEF DESCRIPTION OF THE DRAWINGS

FIG. 1 is an isometric view of an integrated circuit component and a heat sink.

FIG. 2 is an isometric view of the integrated circuit component of FIG. 1.

FIG. 3 is a cross-sectional view of one embodiment of the integrated circuit component of FIG. 1.

FIG. 4 is a cross-sectional view of one embodiment of an integrated heat spreader of the integrated circuit component of FIG. 1.

FIG. 5 is a scanning electron microscope (SEM) picture of one embodiment of a diamond composite material.

FIG. 6 is a scanning electron microscope (SEM) picture of one embodiment of a diamond composite material.

FIG. 7 is a simplified flow diagram of at least one embodiment of a method for manufacturing an integrated circuit component with a diamond composite material.

FIG. 8 is a simplified diagram of one embodiment of a system for performing field-assisted sintering technology (FAST).

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments disclosed herein, an integrated circuit component includes an integrated heat spreader (IHS) that is made from or otherwise includes a diamond composite material. In one embodiment, the diamond composite material is, by volume, 30-65% diamond particles, 0.5-10% chromium, and 20-60% copper. The diamond composite material has a high thermal conductivity, such as a thermal conductivity of at least 600 W/(m·K). In an illustrative embodiment, the diamond composite material is made using field-assisted sintering technology (FAST).

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

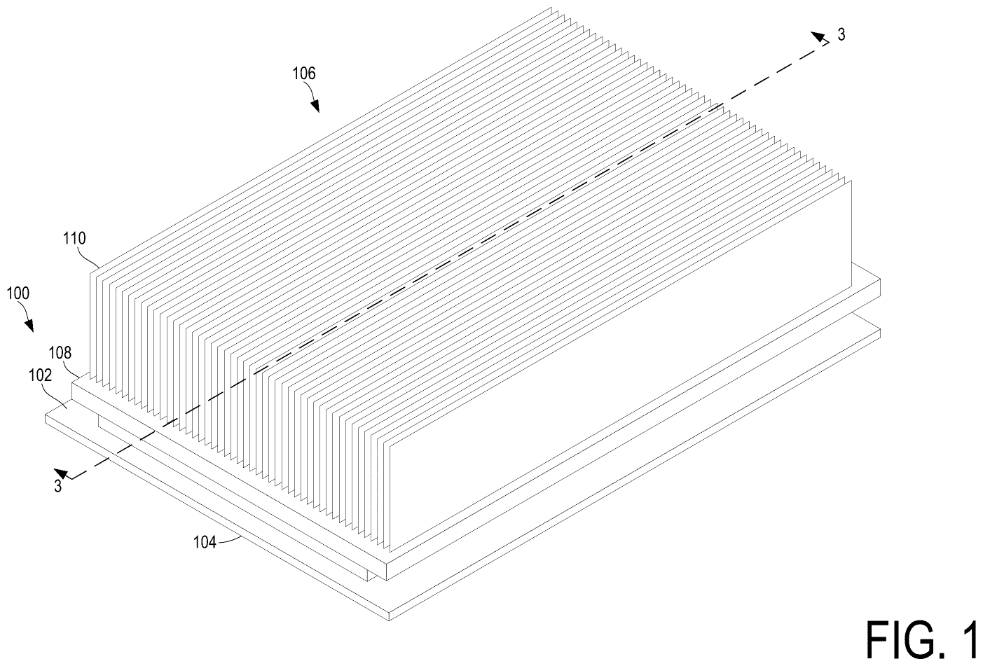

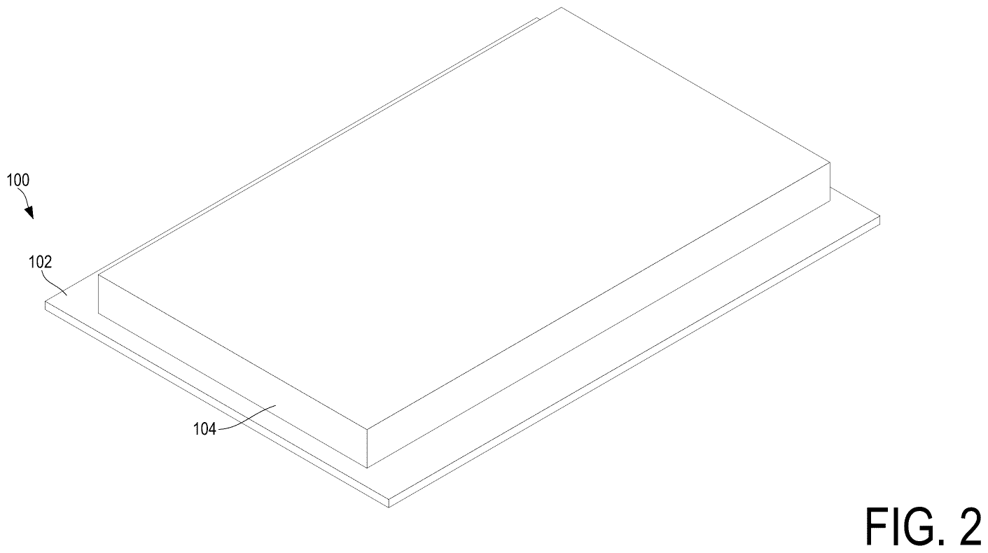

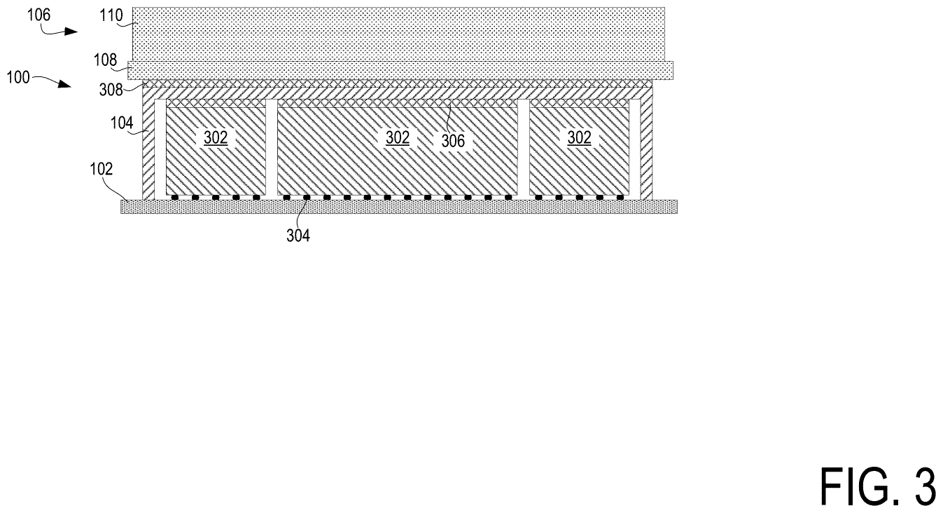

Referring now to FIGS. 1-3, in one embodiment, an integrated circuit component 100 includes a circuit board 102, one or more integrated circuit (IC) dies 302, and an integrated heat spreader (IHS) 104. FIG. 1 shows a perspective view of the integrated circuit component 100 with a heat sink 106 mounted on it, FIG. 2 shows a perspective view of the integrated circuit component 100 without the heat sink 106, and FIG. 3 shows a cross-sectional view of one embodiment of the integrated circuit component 100. In an illustrative embodiment, the one or more IC dies 202 are mounted on the circuit board 102. The integrated circuit component 100 may include other components, such as additional IC dies, components such as capacitors, inductors, voltage regulators, etc.

In an illustrative embodiment, the ICs 302 are connected to the circuit board 102 with solder balls 304. A thermal interface material (TIM) 306 is between the IC dies 302 and the IHS 104. Another TIM 308 may be between the IHS 104 and the heat sink 106. The TIMs 306, 308 may be any suitable material, such as a silver thermal compound.

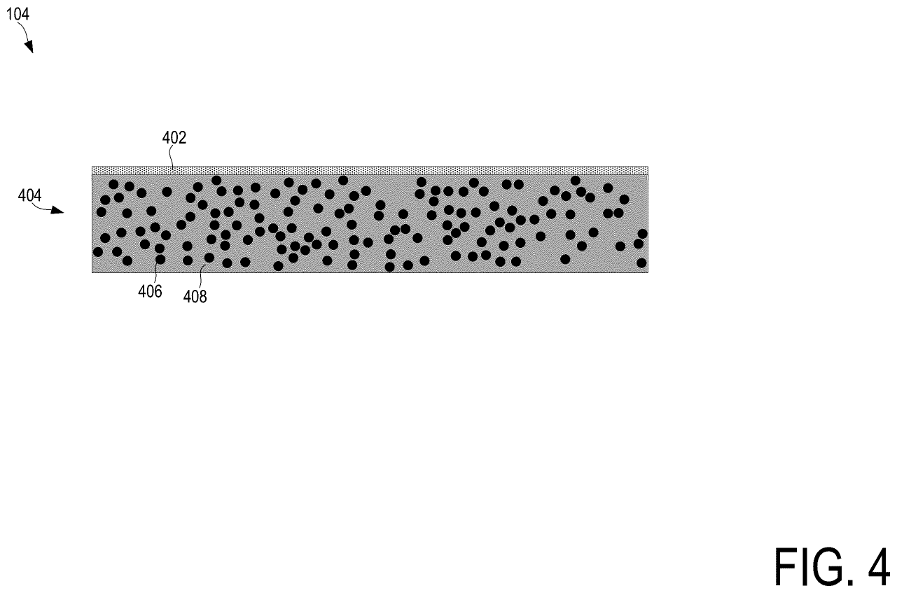

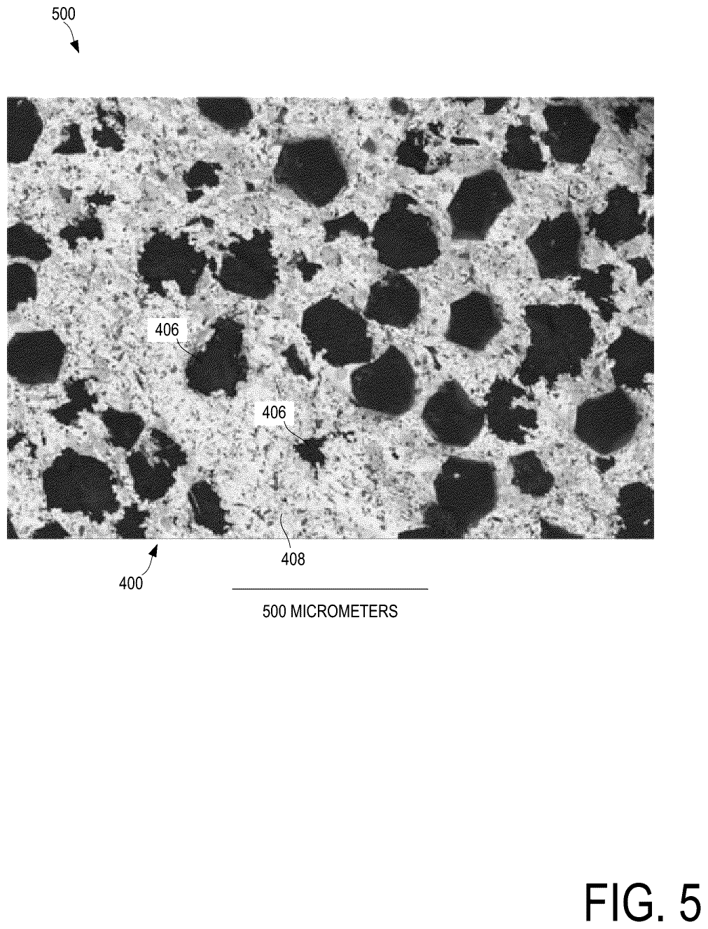

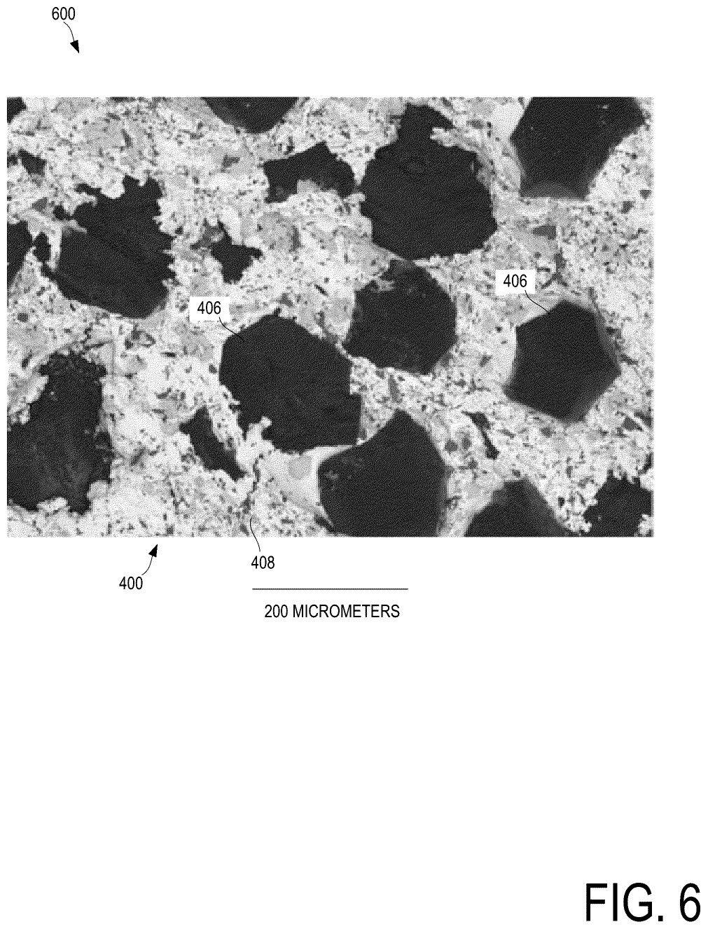

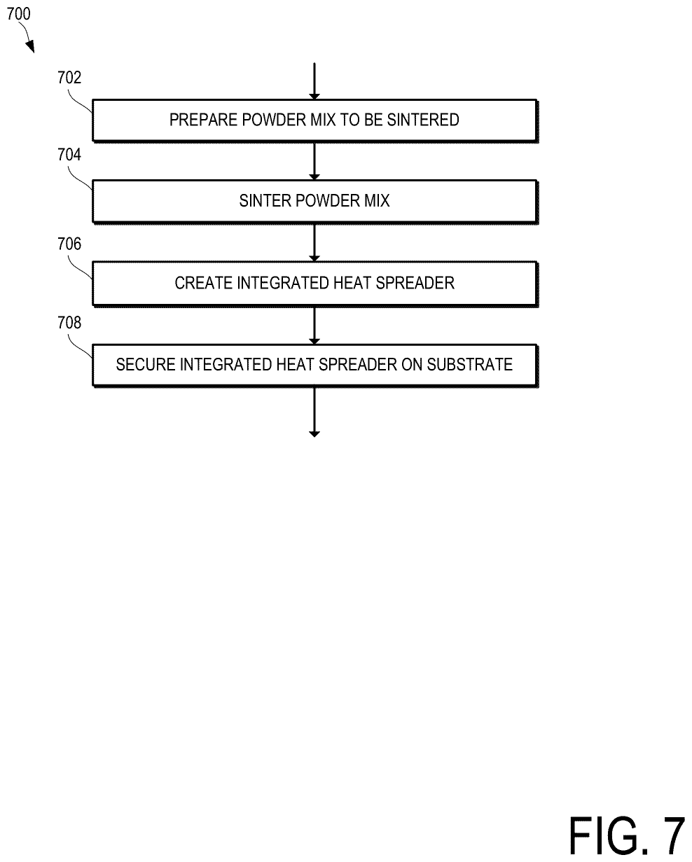

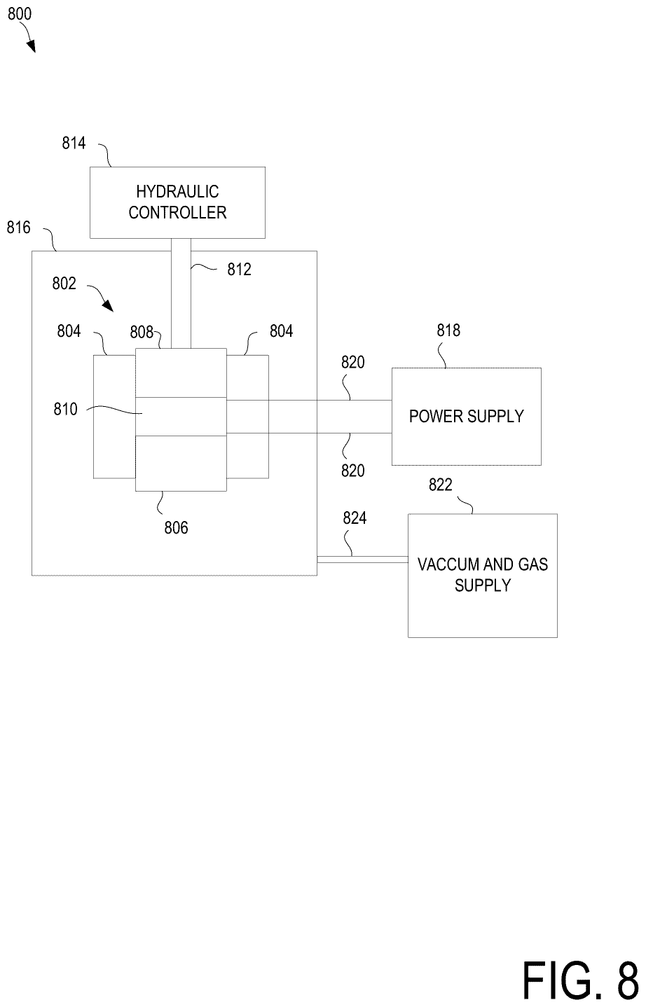

In one embodiment, the IHS 104 is made of or otherwise includes a diamond composite material with a high thermal conductivity, such as 500-1,000 W/(m·K). FIG. 4 shows a cross-sectional view of part of one embodiment of an IHS 104. The IHS 104 may have a layer with diamond composite material 404 and a coating layer 402. The coating layer 402 may be, e.g., copper, silver, gold, tin, nickel, or other suitable material with a relatively high thermal conductivity. The coating layer may have any suitable thickness, such as 5-500 micrometers. The diamond composite material 404 may be made using field-assisted sintering technology (FAST), as described below in more detail in regard to FIGS. 7 and 8. The diamond composite material 404 includes diamond particles 406 and a matrix material 408. FIGS. 5 and 6 show scanning electron microscope pictures 500, 600 of one embodiment of the diamond composite material 404, with diamond particles 406 and a matrix material 408. FIGS. 5 and 6 show good adhesion of the matrix material 408 to the diamond particles 406 and relatively low porosity of the diamond composite material 404.

In one embodiment, the diamond composite material 404 may include, e.g., about 50% diamond particles by volume, about 5% chromium by volume, and about 45% copper or copper alloy, by volume. In tests, such embodiments of the diamond composite material 404 formed by FAST had thermal conductivities in the range of 660-670 W/(m·K). The copper alloy may be any suitable alloy of copper, such as an alloy described below, with enough of an additional metal besides copper to prevent the copper from corroding. In an illustrative embodiment, the chromium helps hold the diamond and copper together during and after the sintering process. The diamond particles 406 may have any suitable diameter or range of diameters, such as 30-300 micrometers. The diamond particles 406 may have a roughly spherical or oval shape. The diamond particles 406 may have an RMS surface roughness of, e.g., 0.1-20 micrometers.

In other embodiments, the diamond composite may include a range of possible materials. For example, in one embodiment, the diamond composite material 404 may have 35-65% diamond particles, 0-10% chromium, 20-60% copper or copper alloy, and 0-10% silver or silver alloy, by weight or by volume. In another embodiment, the diamond composite material 404 may have 30-65% diamond particles, 0-10% chromium, 20-60% copper or copper alloy, 0-10% silver or silver alloy, and 0-25% graphite, by weight or by volume. The graphite used in the diamond composite material 404 may be highly oriented pyrolytic graphite (HOPG) with any suitable dimensions, such as a diameter of 10-300 micrometers and a thickness of 1-50 micrometers. In other embodiments, different types of graphite may be used, such as natural flake graphite, amorphous graphite, lump graphite, synthetic graphite, etc. In another embodiment, the diamond composite material 404 may have 30-60% diamond particles, 0-10% chromium, and 30-70% silver or silver alloy, by weight or by volume. In another embodiment, the diamond composite material 404 may have 30-60% diamond particles, 0-10% chromium, 25-65% silver or silver alloy, and 2-25% graphite, by weight or by volume.

In embodiments with a copper alloy, any suitable copper alloy may be used. Copper may be alloyed with any suitable amount of any material discussed below in order to prevent the copper from corroding without reducing the thermal conductivity too much. The copper alloy may include, e.g., 4% silver and 0.5% zirconium, by weight or by volume. More generally, the copper alloy may include any suitable combination of 40-99% copper, 0-10% silver, 0-5% zirconium, 0-50% nickel, 0-50% zinc, 0-50% tin, 0-50% beryllium, 0-50% chromium, 0-50% aluminum, 0-50% zirconium, and/or 0-50% titanium, by weight or by volume. Similarly, in embodiments with a silver alloy, any suitable silver alloy may be used. The silver alloy may include, e.g., 40-99% silver, 0-10% copper, 0-50% palladium, 0-50% tin, 0-50% gold, 0-50% zinc, 0-50% nickel, 0-50% cadmium, 0-50% indium, and/or 0-50% titanium, by weight or by volume. In some embodiments, the silver alloy may include 3% silicon by weight or by volume.

The illustrative circuit board 102 may be made from ceramic, glass, and/or organic-based materials with fiberglass and resin, such as FR-4. The circuit board 102 may have any suitable length or width, such as 10-500 millimeters. The circuit board 102 may have any suitable thickness, such as 0.2-5 millimeters. The circuit board 102 may support additional components besides the components shown in FIGS. 1-3, such as additional photonic or electronic integrated circuit components, a memory device, additional circuit components, etc.

The one or more IC dies 302 may include any suitable electronic integrated circuit component, such as resistors, capacitors, inductors, transistors, etc. The one or more IC dies 302 may include any suitable analog and/or digital circuitry, such as a processor, a memory, an application-specific integrated circuit (ASIC), a field-programmable gate array (FPGA), etc. The IC dies 302 may have any suitable length or width, such as 1-300 millimeters. The IC dies 302 may have any suitable thickness, such as 0.05-5 millimeters.

In an illustrative embodiment, the IHS 104 includes a diamond composite material 404, as discussed above. Additionally or alternatively, in some embodiments, the IHS 104 may be made of any suitable material with a high thermal conductivity, such as copper, aluminum, other metals, metal alloys, coated metals, combinations of metals, etc.

The illustrative heat sink 106 has a heat sink base 108 and several heat sink fins 110. The fins 110 may be any suitable structure that has a high surface area-to-volume ratio. The fins 110 may be any suitable shape, such as a plane, a rod, a folded sheet, etc. In the illustrative embodiment, the heat sink fins 110 are bonded to the heat sink base 108 by solder, glue, or other adhesive. In other embodiments, the heat sink fins 110 may be removably fastened to the heat sink base 108. In some embodiments, the heat sink 106 may be a unitary piece that includes both the heat sink base 108 and the heat sink fins 110. More generally, the heat sink 106 may be manufactured in any suitable manner, such as extrusion, skiving, stamping, forging, machining, 3D printing, etc.

One purpose of the heat sink 106 is to absorb heat from the integrated circuit component 100 and transfer the heat to air. In some embodiments, a fan (not shown in FIG. 1) may blow air onto and/or through the heat sink fins 110.

The heat sink 106 may be made from any suitable material. In the illustrative embodiment, the heat sink base 108 and the heat sink fins 110 are made from a high-thermal-conductivity material, such as copper, aluminum, or another material with a thermal conductivity greater than 100 W/(m×K). In some embodiments, the heat sink base 108 and the heat sink fins 110 may be made of different material. For example, the heat sink base 108 may be aluminum and the heat sink fins 110 may be copper. In some embodiments, the heat sink base 108 may have more than one layer of different materials. In some embodiments, the heat sink base 108 and/or the heat sink fins 110 may be made of or otherwise include the diamond composite material 404.

The heat sink 106 may have any suitable shape or dimensions. For example, the heat sink 106 may have a width of 10-250 millimeters, a length of 10-250 millimeters, and/or a height of 10-100 millimeters. In an illustrative embodiment, the heat sink 106 has a width of about 75 millimeters, a width of about 150 millimeters, and a height of about 30 millimeters. The thickness of the base plate 108 may be any suitable thickness, such as 1-10 millimeters. In the illustrative embodiment, the base plate 108 has a thickness of about 5 millimeters. The height of the fins 110 may be any suitable height, such as 5-100 millimeters. In some embodiments, the heat sink 106 may be a cold plate used in a liquid cooling system and may not have any external fins 110.

The illustrative heat sink 106 is a rectangular shape. In other embodiments, the heat sink 106 may be any suitable shape, such as a square, a circle, etc. The illustrative heat sink base 108 has a flat surface on the bottom. In the illustrative embodiment, the central region of the bottom of the heat sink base 108 contacts the flat surface of the IHS 104. Heat flows from the central region of the heat sink base 108 to the edges of the heat sink base 108 and into the fins 110. In some embodiments, the heat sink base 108 does not have a flat surface on the bottom. For example, the heat sink base 108 may have a pedestal extruding from the bottom of the heat sink base 108 that contacts some or all of the IHS 104. In some embodiments, the heat sink 106 may include other heat-transferring components such as one or more heat pipes, a thermoelectric heater/cooler, etc.

Referring now to FIG. 7, in one embodiment, a flowchart for a method 700 for creating an integrated circuit component 100 with an IHS 104 with a diamond composite material 404 is shown. The method 700 may be executed by a technician and/or by one or more automated machines. In some embodiments, one or more machines may be programmed to do some or all of the steps of the method 700. Such a machine may include, e.g., a memory, a processor, data storage, etc. The memory and/or data storage may store instructions that, when executed by the machine, cause the machine to perform some or all of the steps of the method 700. The method 700 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, etc. It should be appreciated that the method 700 is merely one embodiment of a method to create one embodiment of the integrated circuit component 100, and other methods may be used to create any suitable embodiment of the integrated circuit component 100. In some embodiments, steps of the method 700 may be performed in a different order than that shown in the flowchart.

The method 700 begins in block 702, in which a powder mix to be sintered in prepared. The powder mix may include diamond particles 406 as well as one or more additional powders, such as copper powder, copper alloy powder, silver powder, silver alloy powder, chromium powder, graphite powder, etc. Copper may be combined with, e.g., 4% silver and 0.5% zirconium, by weight or by volume, to prevent corrosion when powdered. The powder mix may be in any of the ratios described above in regard to the diamond composite material 404, a description of which will not be repeated in the interest of clarity. The particle size for the metallic powders may be, e.g., particles with a diameter over 15-50 micrometers. The powder mix may be blended using, e.g., rotary tumblers, V-blenders, double-cone blenders, etc.

In block 704, the powder mix is sintered using field-assisted sintering technology (FAST). FAST may also be referred to as spark plasma sintering or pulse electric current sintering. FIG. 8 shows a simplified block diagram for a FAST system 800. The FAST system 800 includes a die assembly 802 made up of a die 804, a lower punch 806, and an upper punch 808. The material 810 to be sintered is positioned within the die assembly 802 during sintering. In an illustrative embodiment, the material 810 is the same material throughout. In other embodiments, the material 810 may have different layers, such as a central layer with more diamond particles 406 and one or more exterior layers with fewer or no diamond particles 406. The FAST system 800 includes an actuator arm 812 connected to the upper punch 808 and a hydraulic controller 814 that can actuate the actuator arm 812. In an illustrative embodiment, the die assembly 802 is enclosed in an airtight chamber 816. A power supply 818 is connected by leads 820 to the material 810. A vacuum and gas supply 822 is connected to the airtight chamber 816 by a pipe 824. The FAST system 800 may include additional components, such as a temperature sensor, pyrometer, etc.

In use, the hydraulic controller 814 can actuate the actuator arm 812 to apply a force on the upper punch 808 and apply pressure to the material 810. The hydraulic controller 814 may apply a force of up to, e.g., 250 kilonewtons. The pressure applied to the material 810 may be, e.g., up to 70 megapascals. The power supply 818 may apply any suitable current up to, e.g., 15 kiloamps, at any suitable voltage, such as up to 10 volts. The power supply 818 may generate a direct current (DC) signal, an alternating current (AC) signal, a pulsed DC signal, etc. The vacuum and gas supply 822 may create a vacuum in the chamber 816 down to, e.g., 10 microbar. Additionally or alternatively, the vacuum and gas supply 822 may be able to generate an atmosphere inside the chamber 816 of, e.g., argon or nitrogen.

To sinter the material 810, the FAST system 800 may apply a force to the material and apply a current to the material. The current flows between the boundaries of different grains of the powder, fusing the grains together around the diamond particles 406.

In block 706, an integrated heat spreader 104 is formed from the material 810 being sintered. In some embodiments, the die assembly 802 may be such that the material 810 is sintered into a relatively simple shape, such as a cylinder. In some embodiments, the cylinder may be incorporated into a component such as the IHS 104, or the cylinder may be machined into a desired shape. Additionally or alternatively, the die assembly 802 may be such that the material 810 is formed into a more complicated shape, such as the shape of the IHS 104 shown in FIGS. 1-3. In some embodiments, the die assembly 802 may be such that the material 810 is formed into several IHSs 104 in one sintering step.

In block 708, the IHS 104 is secured to the circuit board 102, forming the integrated circuit component 100.

It should be appreciated that the method 700 is amenable to high-volume manufacturing, as the raw materials are relatively inexpensive and the FAST process can be performed relatively quickly, allowing for production for, e.g., integrated heat sinks 104 for millions of integrated circuit components 100 (e.g., processors) at a relatively small increase in cost compared to a standard integrated heat sink.

It should be appreciated that an IHS 104 is merely one possible use for the diamond composite material 404, and additional uses are envisioned as well. For example, the diamond composite material 404 may be used as or otherwise incorporated into the heat sink base 108, the fins 110, a cold plate, internal frames, chassis material (e.g., for a cell phone, tablet, laptop, etc.), etc.

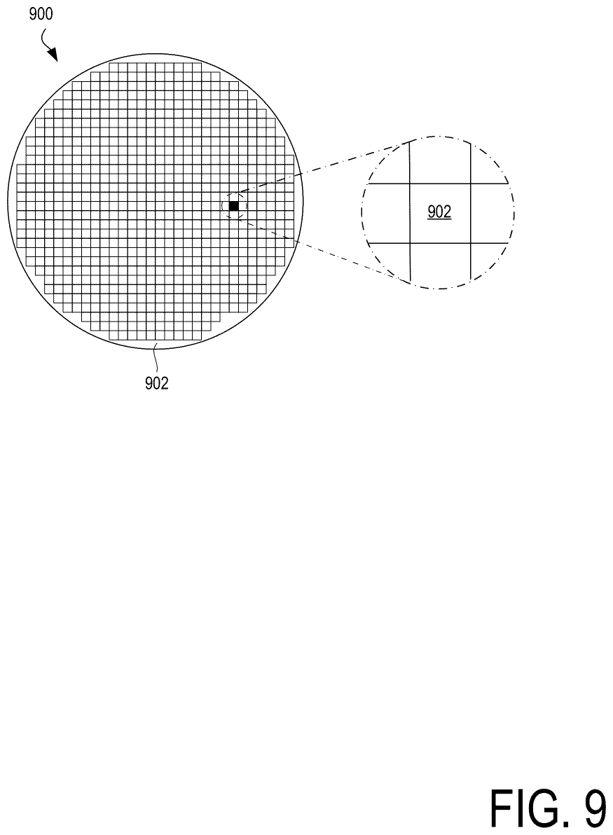

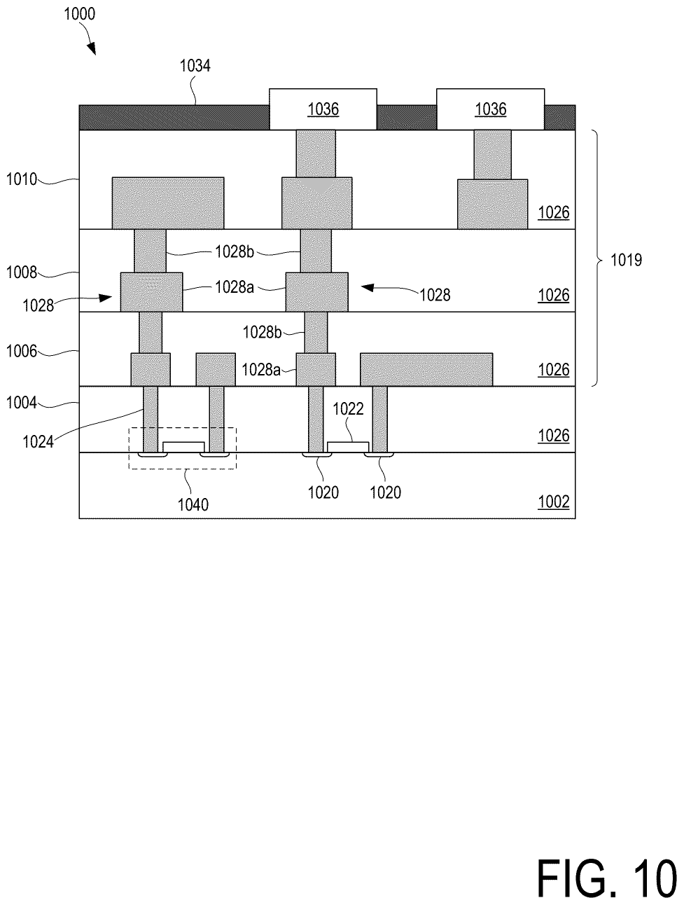

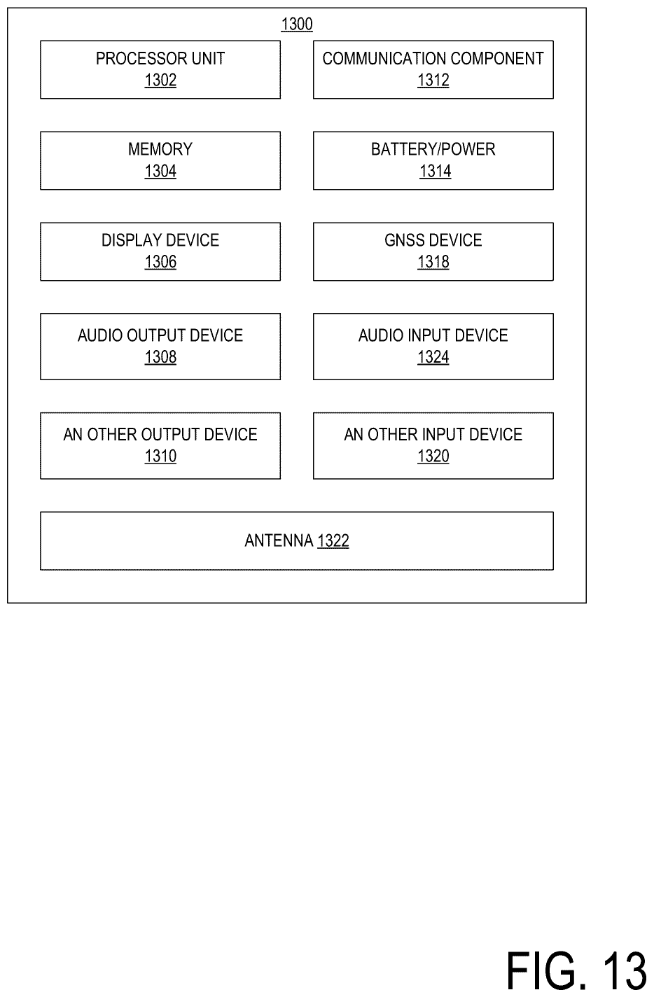

FIG. 9 is a top view of a wafer 900 and dies 902 that may be included in any of the integrated circuit components 100 disclosed herein (e.g., as any suitable ones of the dies 302). The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies 302 disclosed herein. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. Various ones of the integrated circuit components 100 disclosed herein may be manufactured using a die-to-wafer assembly technique in which some dies 302 are attached to a wafer 900 that include others of the dies 302, and the wafer 900 is subsequently singulated.

FIG. 10 is a cross-sectional side view of an integrated circuit device 1000 that may be included in any of the integrated circuit components 100 disclosed herein (e.g., in any of the dies 302). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

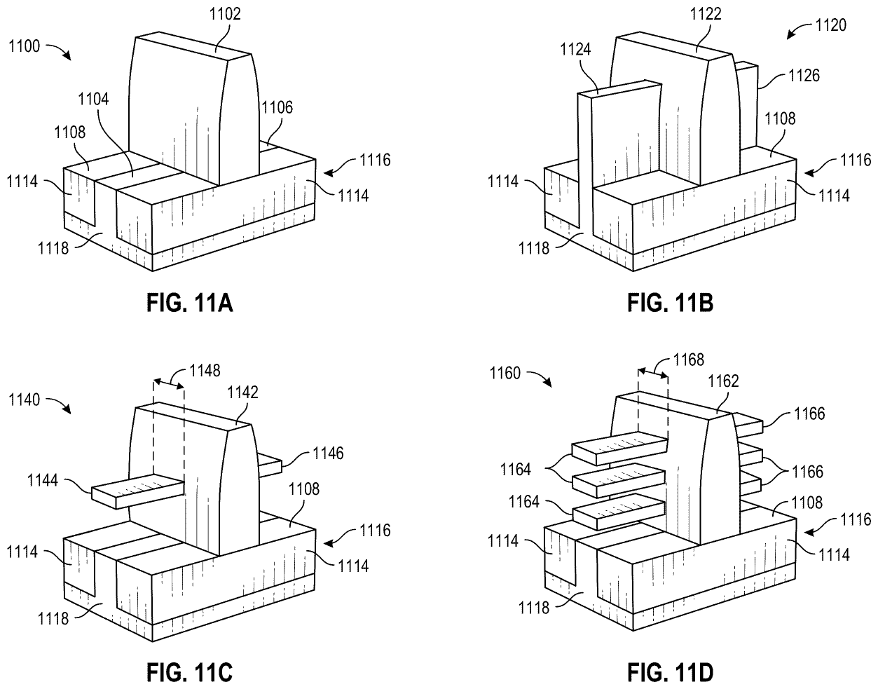

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

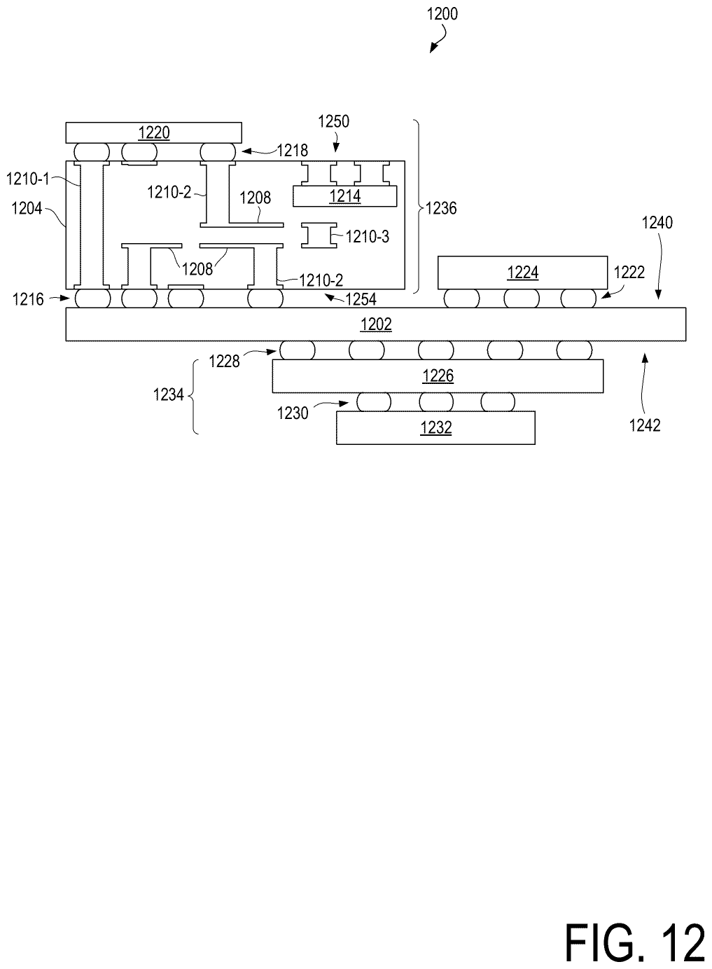

FIG. 12 is a cross-sectional side view of an integrated circuit device assembly 1200 that may include any of the integrated circuit components 100 disclosed herein. In some embodiments, the integrated circuit device assembly 1200 may be an integrated circuit component 100. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the integrated circuit components 100 disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. In some embodiments the circuit board 1202 may be, for example, the circuit board 102. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the integrated circuit components 100 disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein, and may be arranged in any of the integrated circuit components 100 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

### EXAMPLES

Illustrative examples of the technologies disclosed herein are provided below. An embodiment of the technologies may include any one or more, and any combination of, the examples described below.

Example 1 includes an integrated circuit component comprising a substrate; one or more dies mounted on the substrate; and an integrated heat spreader (IHS) mounted on the substrate, the IHS thermally coupled to the one or more dies, wherein at least one layer of the IHS comprises, by weight 30-65% diamond particles; 0.5-10% chromium; and 20-60% copper.

Example 2 includes the subject matter of Example 1, and wherein the at least one layer of the IHS comprises 3-10% chromium by weight.

Example 3 includes the subject matter of any of Examples 1 and 2, and wherein the at least one layer of the IHS comprises 3-10% silver by weight.

Example 4 includes the subject matter of any of Examples 1-3, and wherein the at least one layer of the IHS comprises 2-25% graphite by weight.

Example 5 includes the subject matter of any of Examples 1-4, and wherein the 2-25% graphite by weight comprises 2-25% highly oriented pyrolytic graphite by weight.

Example 6 includes the subject matter of any of Examples 1-5, and wherein the at least one layer of the IHS comprises 0.1-1% zirconium by weight.

Example 7 includes the subject matter of any of Examples 1-6, and wherein the 30-65% diamond particles comprises 30-65% diamond particles with a diameter of 50-200 micrometers.

Example 8 includes the subject matter of any of Examples 1-7, and wherein the at least one layer of the IHS has a thermal conductivity of at least 600 Watts per meter per Kelvin.

Example 9 includes the subject matter of any of Examples 1-8, and wherein the IHS comprises a second layer adjacent the at least one layer, wherein the second layer comprises copper, wherein the second layer has a thickness between 1 and 200 micrometers.

Example 10 includes a composition of matter comprising, by weight 30-65% diamond particles; 0.5-10% chromium; and 20-60% copper.

Example 11 includes the subject matter of Example 10, and further including 3-10% chromium by weight.

Example 12 includes the subject matter of any of Examples 10 and 11, and further including 3-10% silver by weight.

Example 13 includes the subject matter of any of Examples 10-12, and further including 2-25% graphite by weight.

Example 14 includes the subject matter of any of Examples 10-13, and wherein the 2-25% graphite by weight comprises 2-25% highly oriented pyrolytic graphite by weight.

Example 15 includes the subject matter of any of Examples 10-14, and further including 0.1-1% zirconium by weight.

Example 16 includes the subject matter of any of Examples 10-15, and wherein the 30-65% diamond particles comprises 30-65% diamond particles with a diameter of 50-200 micrometers.

Example 17 includes the subject matter of any of Examples 10-16, and wherein composition of matter has a thermal conductivity of at least 600 Watts per meter per Kelvin.

Example 18 includes an integrated heat spreader comprising the composition of matter of Example 10.

Example 19 includes a cold plate comprising the composition of matter of Example 10.

Example 20 includes a frame or chassis of a device comprising the composition of matter of Example 10.

Example 21 includes a composition of matter comprising, by weight 30-60% diamond particles; 0.5-10% chromium; and 25-70% silver.

Example 22 includes the subject matter of Example 21, and further including 3-10% chromium by weight.

Example 23 includes the subject matter of any of Examples 21 and 22, and further including 2-25% graphite by weight.

Example 24 includes the subject matter of any of Examples 21-23, and wherein the 2-25% graphite by weight comprises 2-25% highly oriented pyrolytic graphite by weight.

Example 25 includes the subject matter of any of Examples 21-24, and wherein the 30-60% diamond particles comprises 30-60% diamond particles with a diameter of 50-200 micrometers.

Example 26 includes the subject matter of any of Examples 21-25, and wherein composition of matter has a thermal conductivity of at least 600 Watts per meter per Kelvin.

Example 27 includes an integrated heat spreader comprising the composition of matter of Example 21.

Example 28 includes a cold plate comprising the composition of matter of Example 21.

Example 29 includes a frame or chassis of a device comprising the composition of matter of Example 21.

Example 30 includes a method comprising creating a powder mix comprising, by weight, 30-65% diamond particles, 0.5-10% chromium, and 20-60% copper; and sintering the powder mix using field assisted sintering technology (FAST) to form a diamond composite material.

Example 31 includes the subject matter of Example 30, and further including creating an integrated heat spreader from the diamond composite material.

Example 32 includes the subject matter of any of Examples 30 and 31, and further including creating a plurality of integrated heat spreaders from the diamond composite material of one sintering step.

Example 33 includes the subject matter of any of Examples 30-32, and wherein sintering the powder mix comprises sintering the powder mix in a die assembly comprising a mold for an integrated heat sink.

Example 34 includes the subject matter of any of Examples 30-33, and further including repeating the sintering of the powder mix to create at least one million integrated heat spreaders.

Example 35 includes the subject matter of any of Examples 30-34, and further including creating a cold plate from the diamond composite material.

Example 36 includes the subject matter of any of Examples 30-35, and further including creating a frame or a chassis for a device from the diamond composite material.

Example 37 includes the subject matter of any of Examples 30-36, and wherein the diamond composite material comprises 3-10% chromium by weight.

Example 38 includes the subject matter of any of Examples 30-37, and wherein the diamond composite material comprises 3-10% silver by weight.

Example 39 includes the subject matter of any of Examples 30-38, and wherein the diamond composite material comprises 2-25% graphite by weight.

Example 40 includes the subject matter of any of Examples 30-39, and wherein the 2-25% graphite by weight comprises 2-25% highly oriented pyrolytic graphite by weight.

Example 41 includes the subject matter of any of Examples 30-40, and wherein the diamond composite material comprises 0.1-1% zirconium by weight.

Example 42 includes the subject matter of any of Examples 30-41, and wherein the 30-65% diamond particles comprises 30-65% diamond particles with a diameter of 50-200 micrometers.

Example 43 includes the subject matter of any of Examples 30-42, and wherein the diamond composite material has a thermal conductivity of at least 600 Watts per meter per Kelvin.

1. An integrated circuit component comprising:
a substrate;
one or more dies mounted on the substrate; and
an integrated heat spreader (IHS) mounted on the substrate, the IHS thermally coupled to the one or more dies,
wherein at least one layer of the IHS comprises, by volume:
30-65% diamond particles;
0.5-10% chromium; and
10-60% copper.

2. The integrated circuit component of claim 1, wherein the at least one layer of the IHS comprises 3-10% chromium by volume.

3. The integrated circuit component of claim 1, wherein the at least one layer of the IHS comprises 3-10% silver by volume.

4. The integrated circuit component of claim 3, wherein the at least one layer of the IHS comprises 2-25% graphite by volume.

5. The integrated circuit component of claim 4, wherein the 2-25% graphite by volume comprises 2-25% highly oriented pyrolytic graphite by volume.

6. The integrated circuit component of claim 1, wherein the at least one layer of the IHS comprises 0.1-1% zirconium by volume.

7. The integrated circuit component of claim 1, wherein the 30-65% diamond particles comprises 30-65% diamond particles with a diameter of 50-200 micrometers.

8. The integrated circuit component of claim 1, wherein the at least one layer of the IHS has a thermal conductivity of at least 600 Watts per meter per Kelvin.

9. The integrated circuit component of claim 1, wherein the IHS comprises a second layer adjacent the at least one layer, wherein the second layer comprises copper, wherein the second layer has a thickness between 1 and 200 micrometers.

10. A composition of matter comprising, by volume:
30-65% diamond particles;
0.5-10% chromium; and
10-60% copper.

11. The composition of matter of claim 10, further comprising 3-10% chromium by volume.

12. The composition of matter of claim 10, further comprising 3-10% silver by volume.

13. The composition of matter of claim 12, further comprising 2-25% graphite by volume.

14. The composition of matter of claim 10, further comprising 0.1-1% zirconium by volume.

15. The composition of matter of claim 10, wherein composition of matter has a thermal conductivity of at least 600 Watts per meter per Kelvin.

16. A method comprising:
creating a powder mix comprising, by volume, 30-65% diamond particles, 0.5-10% chromium, and 10-60% copper; and
sintering the powder mix using field assisted sintering technology (FAST) to form a diamond composite material.

17. The method of claim 16, further comprising creating an integrated heat spreader from the diamond composite material.

18. The method of claim 16, further comprising creating a plurality of integrated heat spreaders from the diamond composite material of one sintering step.

19. The method of claim 16, wherein sintering the powder mix comprises sintering the powder mix in a die assembly comprising a mold for an integrated heat sink.

20. The method of claim 16, further comprising repeating the sintering of the powder mix to create at least one million integrated heat spreaders.
